(19) United States
(12) Patent Application Publication
(10) Pub. No.: US 2008/0258242 A1
(43) Pub. Date: Oct. 23, 2008

(54) Low contact resistance ohmic contact for a high electron mobility transistor and fabrication method thereof

(75) Inventors: Xiaobing Mei, Manhattan Beach, CA (US); Ping-Chih Chang, Gardena, CA (US); Michael David Lange, Anaheim, CA (US)

Correspondence Address: POSZ LAW GROUP, PLC, 12040 SOUTH LAKES DRIVE, SUITE 101, RESTON, VA, 20191, US

(73) Assignee: Northrop Grumman Space and Mission Systems Corp., Los Angeles, CA (US)

(21) Appl. No.: 11/785,615

(22) Filed: Apr. 19, 2007

(51) Int. Cl. H01L 29/66; H01L 21/02

(52) U.S. Cl. 257/410; 438/167; 438/597; 257/E49.001; 257/E21.002; 257/194

(57) ABSTRACT

A semiconductor device (100) is formed on a semi-insulating semiconductor substrate (101) including a channel layer (104), a spacer layer (105), an electron supply layer (106), and a barrier layer (108). A composite layer (110) is formed over the barrier layer (108). A metal (116) is deposited over the composite layer (110). The metal (116) is annealed to promote a chemical reaction between the metal (116) and the composite layer (110) in which a portion of the metal sinks into the composite layer (110) and forms an ohmic contact with the composite layer.

### TECHNICAL FIELD

The technical field relates generally to semiconductor devices and semiconductor device fabrication methods, and, more particularly, to High Electron Mobility Transistors (HEMTs) and HEMT fabrication methods.

### BACKGROUND

Future imaging and communication systems will extend the need for higher frequency and bandwidth devices and circuits beyond current device capabilities. The current generation of millimeter-wave (mmW) transceivers and imagers includes High Electron Mobility Transistors (HEMTs) or Heterostructure Field Effect Transistors (HFETs), both of which will be collectively referred to here as HEMTs, operable at frequency bands between 50 and 120 GHz. Further, mmW components, such as amplifiers, operable in G-band frequencies (140-220 GHz) have also been developed.

A conventional HEMT includes a semi-insulating substrate, a channel layer, and an electron supply layer. Electrons from the electron supply layer transfer into the channel layer and form a two-dimensional electron gas (2-DEG) layer for carrying current between a source region and a drain region. The sheet concentration of the accumulated electrons and hence the source to drain region current is modulated by modulating a bias applied to a Schottky barrier gate formed above the channel layer.

Conventionally, ohmic contacts for the source and drain regions of the HEMT have been formed by a physical reaction such as diffusion. For example, a layer of germanium, nickel and gold can be deposited over photoresist patterned source and drain regions, and lift-off of the photoresist is performed to remove unwanted metals. The remaining ohmic contact metal is heated to alloy the metal with the underlying layer source and drain regions by diffusion and thereby form ohmic contacts with the source and drain regions.

Next generation devices will operate in the sub-millimeter wave region to provide benefits such as higher available bandwidth, reduced radar aperture and instrument size, and narrowed beam widths for radar and remote sensing applications by utilizing frequencies from 300 GHz to 3 THz.

However, conventional HEMT fabrication processes, such as the fabrication process discussed above, cannot alone be utilized to manufacture semiconductor HEMTs having ohmic contacts sufficiently stable for sub-millimeter wave operation. Particularly, the alloyed metal of the above ohmic contacts may continue to diffuse into the underlying channel layer, and thereby degrade device performance during operation at high temperatures. In addition, the contact resistance of the above ohmic contacts is too high to achieve the necessary gain.

It would be desirable to have a HEMT fabrication process that would enable the manufacture of a HEMT including stable and reliable source and drain contacts with low contact resistance. It would be further desirable for such a HEMT fabrication process to also satisfy the production efficiency and complexity levels of current HEMT fabrication processes. It would be further desirable for such a HEMT fabrication process to have robustness in a manufacturing environment.

### SUMMARY

The present disclosure concerns a semiconductor device fabrication method in which a semiconductor device is formed on a semi-insulating semiconductor substrate including a channel layer, an electron supply layer disposed above the channel layer and a barrier layer disposed over the electron supply layer. A composite layer is formed over the electron supply layer and a metal is deposited over the composite layer. The metal is annealed to promote a chemical reaction between the metal and the composite layer in which a portion of the metal sinks into the composite layer to form an ohmic contact therewith.

The present disclosure also concerns a high electron mobility transistor (HEMT) including a semi-insulating substrate, a buffer layer, a channel layer disposed over the buffer layer, a spacer layer and an electron supply layer disposed over the channel layer for forming a two-dimensional electron gas (2-DEG) layer in the channel layer, a barrier layer disposed over the electron supply layer for forming a Schottky gate barrier, a composite layer disposed over the barrier layer for providing source and drain regions electrically coupled to the 2-DEG layer, and source and drain contacts respectively disposed on the composite layer. The source and drain contacts include metal sunken into the composite layer by a chemical reaction therewith.

### BRIEF DESCRIPTION OF THE DRAWINGS

The accompanying figures, where like reference numerals refer to identical or functionally similar elements throughout the separate views and which together with the detailed description below are incorporated in and form part of the specification, serve further to illustrate various embodiments and to explain various principles and advantages all in accordance with the present invention.

FIGS. 1A-1C are diagrams illustrating a semiconductor device fabrication method according to various embodiments;

FIG. 2 is a scanning transmission electron micrograph (STEM) image showing a portion of a semiconductor device fabricated according to the method of FIGS. 1A-1C; and

FIG. 3 is a diagram illustrating a measured transfer curve of a semiconductor device fabricated according to the method of FIGS. 1A-1C, and a measured transfer curve of a related art semiconductor device.

### DETAILED DESCRIPTION

Various embodiments of a semiconductor device and a fabrication method thereof will be discussed with reference to the drawings in which like numbers reference like components, and in which a single reference number may be used to identify an exemplary one of multiple like components.

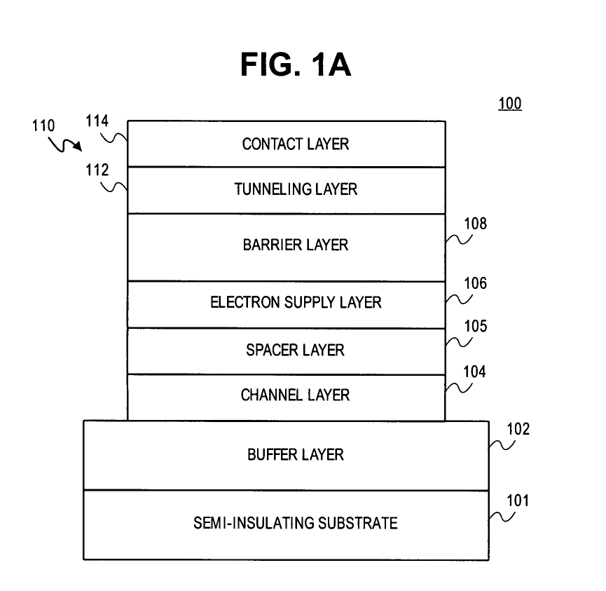

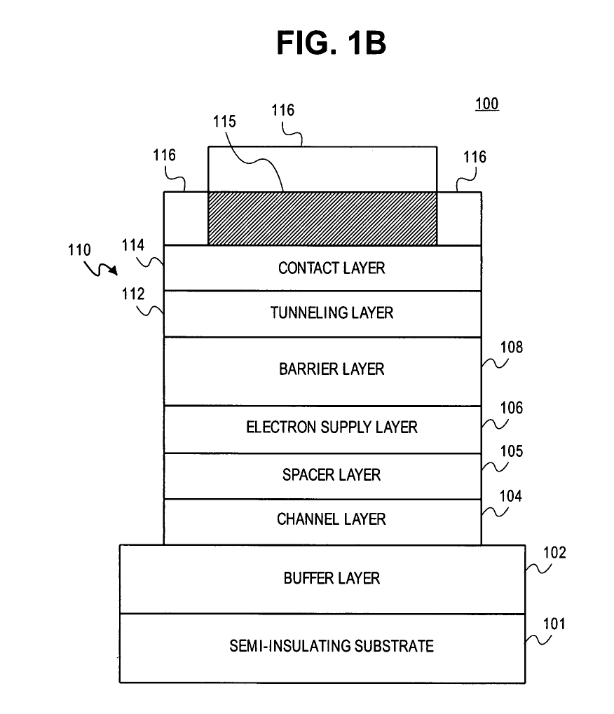

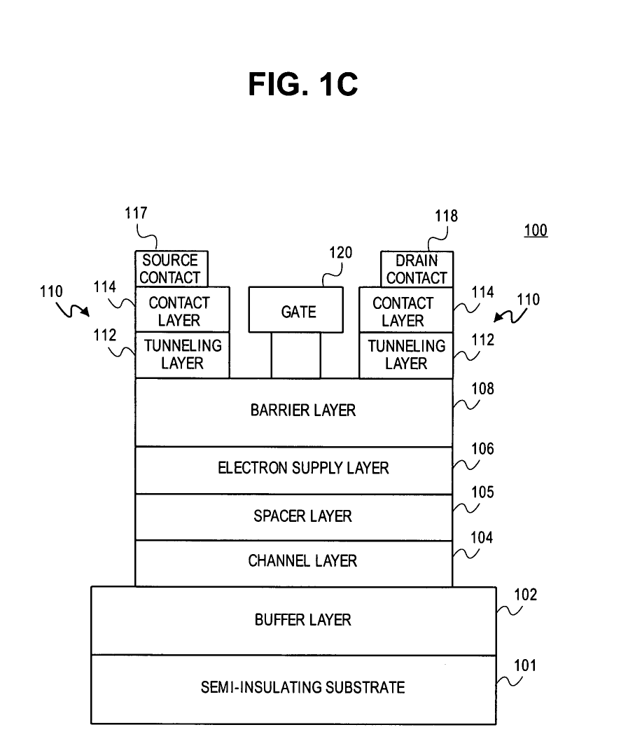

Referring to FIGS. 1A-1C, a method of fabricating a semiconductor device such as a High Electron Mobility Transistor (HEMT) or Heterostructure Field Effect Transistor (HFET), both of which will be collectively referred to here as HEMT 100, will be discussed. The HEMT 100 can be fabricated on a semi-insulating substrate 101, such as, for example, indium phosphide (InP) or gallium nitride (GaN).

Referring to FIG. 1A, a buffer layer 102 composed of, for example, un-doped InAlAs is formed on the substrate 101. The buffer layer 102 isolates layers to be formed above the buffer layer 102 from the substrate 101, thereby preventing any possible contamination on the substrate 101 from affecting the device. The buffer layer 102 also presents a crystalline surface for epitaxial growth that is smoother than the surface of the substrate 101.

A channel layer 104, a thin spacer layer 105, an electron supply layer 106 and a barrier layer 108 are sequentially formed on the buffer layer 102. The channel layer 104 can be composed of un-doped InGaAs. The electron supply layer 106 can be composed of silicon. The spacer layer 105 and the barrier layer 108 can be composed of un-doped InAlAs. Alternatively, the channel layer 104 can be a composite channel composed of InGaAs/InAs.

The electron supply layer 106 includes donor atoms that provide electrons to the channel layer 104. The electrons are confined in the channel layer 104 due to a resulting offset in the conduction band between the spacer layer 105 and the channel layer 104. The spacer layer 105 separates the free electrons from the donor atoms and thereby enhances mobility in the channel layer 104. The high mobility free electron layer in the channel layer 104 is referred to as a two-dimensional electron gas (2-DEG) layer.

A composite layer 110 composed of a heavily doped tunneling layer 112 and a heavily doped contact layer 114 is formed over the barrier layer 108. The tunneling layer 112 can be composed of n⁺ doped InAlAs and the contact layer 114 can be composed of n⁺ doped InGaAs. Silicon can be used for the doping. The heavily doped tunneling layer 112 and the heavily doped contact layer 114 assist electron tunneling between an ohmic contact to be deposited thereon and the channel layer 104. Further, the composite layer 110 defines a source region and a drain region electrically coupled to the 2-DEG layer of the channel layer 104.

Referring to FIG. 1B, the composite layer 110 is patterned with photoresist 115 by conventional photolithography techniques and a metal stack 116 is deposited over the composite layer 110. The metal stack 116 can be composed of, for example, platinum, titanium and gold. The metal stack 116 can be deposited by sequentially evaporating a first layer of platinum, a layer of titanium, a second layer of platinum and a layer of gold over the photoresist 115.

Referring to FIG. 1C, the photoresist 115 is lifted off so that portions of the metal stack remain on the composite layer 110 to thereby form source and drain contacts 117, 118 with the source and drain regions (of the composite layer 110). The metal stack (source and drain contacts 117, 118) is annealed to promote a chemical reaction between a first layer of platinum on the contact layer 114 (the interfacial platinum layer) and the contact layer 114 itself in which a portion of the platinum sinks into the contact layer 114 and forms an ohmic contact and a stable interface with the composite layer 110.

In the chemical reaction, the platinum and InGaAs of the contact layer 114 undergo a solid-state amorphization reaction in which the interfacial surfaces of the platinum and the InGaAs intermix and form an amorphous intermixed layer composed of platinum, gallium and arsenic, which grows in a planar fashion during annealing. Following the growth of the amorphous intermixed layer, platinum will chemically bond with the arsenic. The reaction is self-terminating, and thereby forms a stable contact. The amorphous layer formation is discussed in the publication entitled “Amorphous phase formation and initial interfacial reactions in the platinum/GaAs system,” authored by Dae-Hong Ko and Robert Sinclair, and published in J. Appl. Phys., Vol. 72, No. 5, pgs. 2036-2042, on September 1992, the contents of which are hereby incorporated by reference.

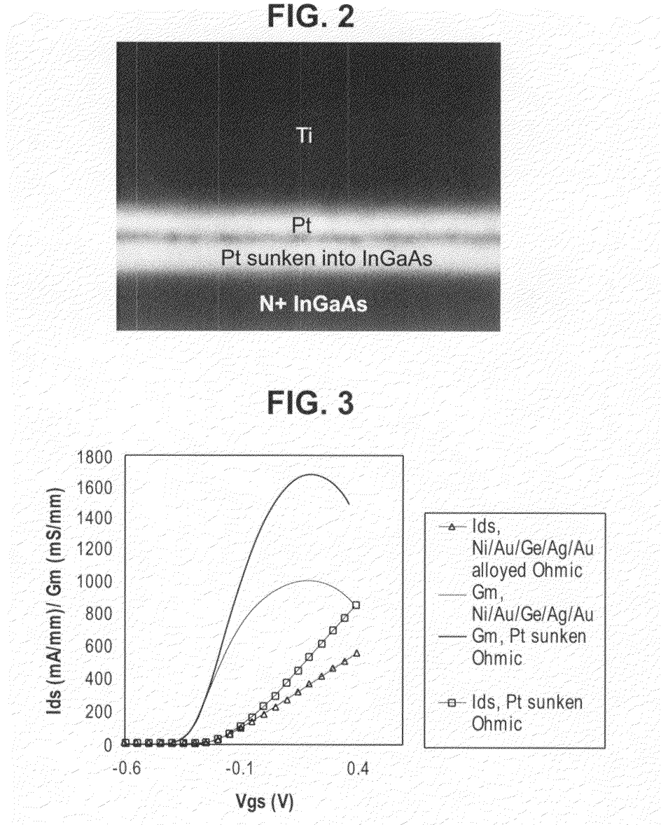

A scanning transmission electron micrograph (STEM) image of the platinum sunken into the contact layer 114 after the chemical reaction is shown in FIG. 2. The annealing can be performed at a temperature of, for example, 200-300 degrees Celsius. However, the specific temperature will depend upon the annealing time.

Returning to FIG. 1C, a gate recess is formed in the composite layer 110 and a gate 120 is formed between the source and drain regions of the composite layer 110 by conventional gate formation techniques. The gate 120 can be formed by an evaporation process in which a metal such as titanium, platinum and gold or a combination thereof is heated to the point of vaporization and then evaporated and lifted off to form the gate 120. The barrier layer 108 provides a Schottky barrier to the gate 120.

The epitaxial layer structure of the buffer layer 102, channel layer 104, spacer layer 105, electron supply layer 106, barrier layer 108 and composite layer 110 can be formed by, for example, epitaxial growth on the semi-insulating substrate 101 by molecular beam epitaxy (MBE), or alternatively by chemical vapor deposition (CVD) techniques such as, for example, metalorganic chemical vapor deposition.

Thereby, the novel semiconductor fabrication method discussed above can be utilized to fabricate the HEMT 100 including a buffer layer 102 disposed on a semi-insulating substrate 101, a channel layer 104 disposed above the buffer layer 102, a spacer layer 105 disposed above the channel layer 104, an electron supply layer 106 disposed above the spacer layer 105, a barrier layer 108 disposed above the spacer layer 106, a composite layer 110 disposed above the barrier layer 108 for defining source and drain regions, and metal stacks having sunken platinum at the metal-semiconductor interface for providing source and drain ohmic contacts 117, 118 with the source and drain regions. The highly doped composite layer 110 assists electron tunneling between the source and drain ohmic contacts 117, 118 and the channel layer 104.

Referring to FIG. 3, transfer curves of a HEMT 100 fabricated to include ohmic contacts formed by sunken platinum according to the method of FIGS. 1A-1C, and a related art HEMT in which the ohmic contacts were formed by a Ni/Au/Ge/Ag/Au alloyed contact were measured in order to compare the drain current (Ids) and transconductance (Gm) across a gate voltage range (Vgs). The HEMT 100 having ohmic contacts formed by sunken platinum demonstrated superior peak Gm and higher overall drain current in comparison to the related art HEMT. Particularly, the HEMT 100 demonstrated a peak Gm of approximately 1675 mS/mm in comparison to a peak Gm of 1010 mS/mm for the related art HEMT. Further, the ohmic contact resistance of the platinum-sunken ohmic contacts of the HEMT 100 was measured at 0.04 Ω·mm, while the ohmic contact resistance of the alloyed contact of the conventional HEMT was measured at 0.11 Ω·mm. That is, forming the ohmic contacts according to the novel semiconductor fabrication method discussed above resulted in a 63% reduction in contact resistance and a 60% increase in peak Gm.

Wafers manufactured with the fabrication process shown in FIGS. 1A-1C demonstrated an average DC yield over 85%, thereby demonstrating the manufacturability of wafers using the above-described process. Further, gain amplifiers incorporating the HEMT 100 demonstrated a peak gain of 5 dB at 265 GHz and a measured circuit MAG/MSG of 3 dB maximum available gain at 300 GHz. That is, the HEMT 100 enables application of a gain amplifier at frequencies above 200 GHz to 300 GHz, and potentially even higher frequencies.

The apparatuses and methods discussed above and the inventive principles thereof are intended to and will provide a semiconductor device having improved ohmic contacts for the source and drain regions of a HEMT. It is expected that one of ordinary skill given the above described principles, concepts and examples will be able to implement other alternative procedures and constructions that offer the same benefits. It is anticipated that the claims below cover many such other examples.

1. A method of forming a semiconductor device on a semi-insulating substrate including a channel layer, an electron supply layer disposed above the channel layer and a barrier layer disposed above the electron supply layer, the method comprising:
forming a composite layer over the barrier layer;
depositing a metal over the composite layer; and
annealing the metal to promote a chemical reaction between the metal and the composite layer in which a portion of the metal sinks into the composite layer and forms an ohmic contact with the composite layer.

2. The method of claim 1, wherein the depositing of the metal over the composite layer further includes evaporating platinum over the composite layer.

3. The method of claim 2, wherein:
the forming of the composite layer further includes forming an n⁺ doped InAlAs layer over the barrier layer and an n⁺ doped InGaAs layer over the n⁺ doped InAlAs layer to enhance electron tunneling between the platinum and the channel layer; and
the platinum chemically reacts with the n⁺ doped InGaAs layer during the annealing.

4. The method of claim 1, wherein the forming of the composite layer further includes growing the composite layer over the barrier layer by molecular beam epitaxial growth.

5. The method of claim 1, wherein the annealing of the metal is performed at a temperature between 200-300 degrees Celsius.

6. The method of claim 1, wherein the semi-insulating semiconductor substrate is an indium phosphide (InP) substrate.

7. The method of claim 1, wherein:
the channel layer includes undoped InGaAs;
the depositing of the metal over the composite layer further includes evaporating platinum over the composite layer; and
the forming the composite layer further includes forming an n⁺ doped InAlAs layer over the barrier layer and an n⁺ doped InGaAs layer over the n⁺ doped InAlAs layer to enhance electron tunneling between the platinum and the channel layer.

8. The method of claim 1, wherein the depositing of the metal over the composite layer further includes evaporating a first layer of platinum, a layer of titanium, a second layer of platinum and a layer of gold over the composite layer.

9. A method of forming a high electron mobility transistor (HEMT) including a channel layer formed above a semi-insulating substrate, a spacer layer and an electron supply layer formed above the channel layer for forming a two-dimensional electron gas (2-DEG) layer in the channel layer, and a barrier layer disposed above the electron supply layer, the method comprising:
forming a composite layer of heavily doped semiconductor material over the barrier layer;
evaporating a metal stack over the composite layer; and
annealing the metal stack to promote a chemical reaction between a portion of the metal stack and the composite layer in which the portion of the metal stack sinks into the composite layer and forms an ohmic contact with the composite layer.

10. The method of claim 9, wherein the forming of the composite layer further includes depositing a tunneling layer comprising n⁺ InAlAs over the barrier layer and depositing a contact layer comprising n⁺ InGaAs on the tunneling layer.

11. The method of claim 9, wherein the evaporating of the metal stack over the composite layer further includes evaporating a first layer of platinum, a layer of titanium, a second layer of platinum and a layer of gold over the composite layer.

12. The method of claim 11, wherein the annealing of the metal stack further includes annealing the metal stack at a temperature between 200 and 300 degrees Celsius, wherein a portion of the first layer of platinum sinks into the contact layer to form the ohmic contact with the composite layer.

13. The method of claim 9, wherein the evaporating of the metal stack over the composite layer further includes:
patterning the composite layer with a photoresist;
evaporating the metal stack over the patterned composite layer; and
lifting off the photoresist so that a portion of the metal stack remains on the composite layer.

14. The method of claim 9, wherein the semi-insulating semiconductor substrate is an indium phosphide (InP) substrate, the spacer layer includes silicon, and the channel layer includes undoped InGaAs.

15. A high electron mobility transistor (HEMT), comprising:
a semi-insulating substrate;
a channel layer disposed over the substrate;
a spacer layer and an electron supply layer disposed over the channel layer for forming a two-dimensional electron gas (2-DEG) layer in the channel layer;
a barrier layer disposed over the electron supply layer for forming a Schottky gate barrier;
a composite layer disposed over the barrier layer for providing source and drain regions electrically coupled to the 2-DEG layer; and
source and drain contacts disposed on the composite layer, the source and drain contacts including a metal sunken into the composite layer by a chemical reaction with the composite layer.

16. The HEMT of claim 15, wherein:
the composite layer includes a tunneling layer comprising n⁺ doped InAlAs and a contact layer comprising n⁺ doped InGaAs, the tunneling layer enhancing electron tunneling between the metal and the channel layer; and
the metal is platinum sunken into the contact layer.

17. The HEMT of claim 15, wherein the metal of each of the source and drain contacts includes platinum, wherein a layer of the platinum is sunken into the composite layer, and a layer of platinum is disposed above the sunken layer of platinum.

18. The HEMT of claim 15, wherein the semi-insulating substrate is an indium phosphide (InP) substrate.

19. The HEMT of claim 18, wherein the channel layer includes undoped InGaAs, and the barrier layer includes undoped InAlAs.

20. The HEMT of claim 18, wherein each of the source and drain contacts further includes a first layer of platinum as the metal sunken into the composite layer, and a second layer of platinum disposed above the first layer.
